(19) United States
(12) Patent Application Publication
(10) Pub. No.: US 2022/0173292 A1
(43) Pub. Date: Jun. 2, 2022

(54) Semiconductor Device

(71) Applicant: EPISTAR CORPORATION, Hsinchu (TW)

(72) Inventors: Ching-Hsing SHEN, Hsinchu (TW); Wen-Luh LIAO, Hsinchu (TW); Chen OU, Hsinchu (TW); Shih-Chang LEE, Hsinchu (TW); Hui-Fang KAO, Hsinchu (TW); Yun-Chung CHOU, Hsinchu (TW)

(21) Appl. No.: 17/456,858

(22) Filed: Nov. 29, 2021

Related U.S. Application Data
(60) Provisional application No. 63/119,173, filed on Nov. 30, 2020.

(51) Int. Cl. H01L 33/62

(52) U.S. Cl. CPC H01L 33/62

(57) ABSTRACT

The present disclosure provides a semiconductor device. The semiconductor device includes an epitaxial stack including a mesa region and a lower region; a first pad on the lower region and a second pad on the mesa region; a first contact between the epitaxial stack and the first pad; a passivation structure covering the epitaxial stack and including a first opening; and a first metal structure in the first opening and disposed between the first contact and the first pad; wherein the first metal structure includes a first top surface away from the epitaxial stack, and the passivation structure including a second top surface at a position corresponding to the lower region and away from the epitaxial stack, and a first height difference between the first top surface and the second top surface is less than 3 μm and larger than zero; and wherein the first metal structure includes a first width adjacent to the first contact and a second width adjacent to the first pad, and the second width is larger than the first width.

### CROSS REFERENCE TO RELATED APPLICATIONS

This application claims the benefit of U.S. Provisional Application Ser. No. 63/119,173, filed on Nov. 30, 2020, the entire content of which is hereby incorporated by reference.

### TECHNICAL FIELD

The disclosure relates to a semiconductor device, and particularly to a light-emitting device.

### DESCRIPTION OF BACKGROUND ART

Light-emitting diodes (LEDs) are widely used as solid-state light sources. Compared to conventional incandescent light lamps or fluorescent light tubes, LEDs have advantages such as lower power consumption and longer lifetime, and therefore LEDs gradually replace the conventional light sources and are applied to various fields such as traffic lights, back light modules, street lighting, and biomedical device.

### SUMMARY OF THE INVENTION

The present disclosure provides a semiconductor device. The semiconductor device includes an epitaxial stack including a mesa region and a lower region; a first pad on the lower region and a second pad on the mesa region; a first contact between the epitaxial stack and the first pad; a passivation structure covering the epitaxial stack and including a first opening; and a first metal structure in the first opening and disposed between the first contact and the first pad; wherein the first metal structure includes a first top surface away from the epitaxial stack, and the passivation structure including a second top surface at a position corresponding to the lower region and away from the epitaxial stack, and a first height difference (H1) between the first top surface and the second top surface is less than 3 μm and larger than zero; and wherein the first metal structure includes a first width adjacent to the first contact and a second width adjacent to the first pad, and the second width is larger than the first width.

The present disclosure provides a semiconductor device. The semiconductor device includes an epitaxial stack including a mesa region and a lower region; a first pad on the lower region and including a first top surface away from the epitaxial stack; a second pad on the mesa region; and a first metal bump on the first top surface and including a first upper surface away from the epitaxial stack; wherein the first top surface includes a first morphology and the first upper surface includes a second morphology different from the first morphology.

### BRIEF DESCRIPTION OF THE DRAWINGS

The foregoing aspects and many of the attendant advantages of this disclosure will become more readily appreciated as the same becomes better understood by reference to the following detailed description, when taken in conjunction with the accompanying drawings, wherein:

FIG. 1A is a schematic cross-sectional view of a semiconductor device in accordance with an embodiment of the present application;

FIG. 1B is an enlarge image of FIG. 1 of a left-hand side area with rectangle dot line;

FIG. 1C is an enlarge image of FIG. 1 of a right-hand side area with rectangle dot line;

FIG. 2 is a schematic top view of a semiconductor device in accordance with an embodiment of the present application;

FIG. 3 is a schematic cross-sectional view of a semiconductor device in accordance with an embodiment of the present application;

FIG. 4A is a schematic cross-sectional view of a semiconductor device in accordance with an embodiment of the present application;

FIG. 4B is a schematic cross-sectional view of a semiconductor device in accordance with an embodiment of the present application;

FIG. 5A is a schematic cross-sectional view of a semiconductor device in accordance with an embodiment of the present application;

FIG. 5B is a schematic cross-sectional view of a semiconductor device in accordance with an embodiment of the present application;

FIG. 5C is a schematic cross-sectional view of a semiconductor device in accordance with an embodiment of the present application;

FIG. 6A is a schematic cross-sectional view of a semiconductor device in accordance with an embodiment of the present application;

FIG. 6B shows a shape of the metal bump;

FIG. 6C shows a shape of the metal bump;

FIG. 7 is a schematic cross-sectional view of a semiconductor device in accordance with an embodiment of the present application;

FIG. 8A is an SEM image of a semiconductor device in accordance with an embodiment of the present application;

FIG. 8B is a cross section view of semiconductor device along A-A′ line shown in FIG. 8A;

FIG. 9 is a top view of a light-emitting module including the semiconductor device disclosed in the present disclosure;

FIG. 10 is a cross sectional view of a part of a sensing module including the semiconductor device disclosed in the present disclosure.

### DETAILED DESCRIPTION OF PREFERRED EMBODIMENTS

Exemplary embodiments of the present disclosure will be described in detail with reference to the accompanying drawings hereafter. The following embodiments are given by way of illustration to help those skilled in the art fully understand the spirit of the present disclosure. Hence, it should be noted that the present disclosure is not limited to the embodiments herein and can be realized by various forms. Further, the drawings are not precisely scaled and components may be exaggerated in view of width, height, length, etc. Herein, the similar or identical reference numerals will denote the similar or identical components throughout the drawings.

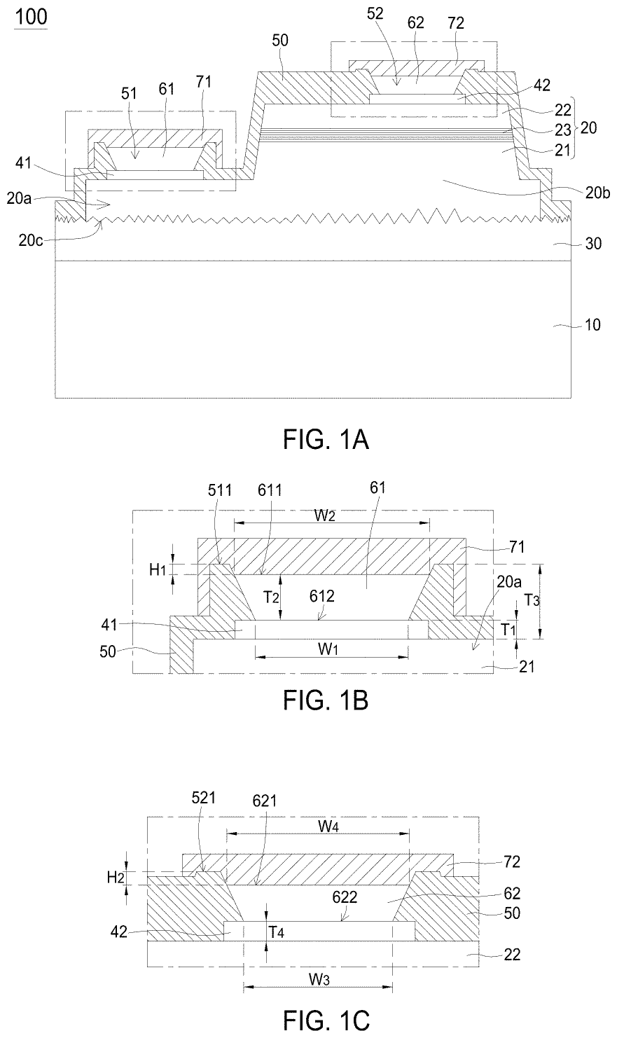

FIG. 1A is a schematic cross-sectional view of an embodiment of a semiconductor device 100. The semiconductor device 100 includes a base 10, an epitaxial stack 20 on the base 10, a bonding layer 30 between the base 10 and the epitaxial stack 20. The epitaxial stack 20 includes a first semiconductor structure 21, a second semiconductor structure 22 and an active region 23 between the first semiconductor structure 21 and the second semiconductor structure 22. The epitaxial stack 20 includes a lower region 20a and a mesa region 20b where the active region 23 and the second semiconductor structure 22 are located. The lower region 20a is devoid of the active region 23 and the second semiconductor structure 22. The epitaxial stack 20 further includes a surface 20c facing the base 10 and having a roughing structure. The semiconductor device 100 includes a first contact 41 on the lower region 20a and a second contact 42 on the mesa region 20b.

The semiconductor device 100 further includes a passivation structure 50 covers the epitaxial stack 20. The passivation structure 50 includes a first opening 51 and a second opening 52. The passivation structure 50 covers one part of the first contact 41 and one part of the second contact 42. In the present embodiment, the semiconductor device 100 further includes a first metal structure 61 filling in the first opening 51 for electrically connecting to the first contact 41, a second metal structure 62 filling in the second opening 52 for electrically connecting to the second contact 42, a first pad 71 located on the first metal structure 61 and a second pad 72 located on the second metal structure 62.

FIGS. 1B and 1C are respectively enlarge images of FIG. 1 of a left-hand side area with rectangle dot line and a right-hand side area with rectangle dot line. As shown in FIG. 1B, the first metal structure 61 includes a first top surface 611 away from the epitaxial stack 20 and a first bottom surface 612 opposite to the first top surface 611, and the passivation structure 50 includes a second top surface 511 at a position corresponding to the lower region 20a and is the topmost surface thereat. The first top surface 611 and the second top surface 511 are not coplanar. In the embodiment, the first top surface 611 is lower than the second top surface 511 in a vertical direction. That is, the first top surface 611 is closer to the lower region 20a than the second top surface 511 to the lower region 20a. In the embodiment, a first height difference H1 between the first top surface 611 and the second top surface 511 is less than 3 μm and larger than zero.

The first bottom surface 612 of the first metal structure 61 connects to the first contact 41 and has a first width W1. The first top surface 611 has a second width W2 larger than the first width W1. In the embodiment, since the first top surface 611 is lower than the second top surface 511, the first metal structure 61 is devoid of covering the second top surface 511 of the passivation structure 50. The first pad 71 is disposed on the first metal structure 61 and the passivation structure 50 and covers the second top surface 511 and the first top surface 611. The first contact 41 has a first thickness T1 and the first metal structure 61 has a second thickness T2. The passivation structure 50 has a third thickness T3 and the second contact 42 has a fourth thickness T4. In the embodiment, the second thickness T2 is larger than the first thickness T1, and the second thickness T2 is smaller than the third thickness T3. For example, the first thickness T1 is between 0.1 μm and 1 μm, the second thickness T2 is between 0.6 μm and 8 μm, the third thickness T3 is between 1 μm and 10 μm, and the fourth thickness T4 is between 0.1 μm and 1 μm.

As shown in FIG. 1C, the second metal structure 62 includes a third top surface 621 away from the epitaxial stack 20 and a second bottom surface 622 opposite to the third top surface 621, and the passivation structure 50 includes a fourth top surface 521 at a position corresponding to the mesa region 20b and is the topmost surface thereat. The third top surface 621 and the fourth top surface 521 are not coplanar. In the embodiment, the third top surface 621 is lower than the fourth top surface 521 in the vertical direction. In the embodiment, a second height difference H2 between the third top surface 621 and the fourth top surface 521 is less than 3 μm and larger than zero. The second bottom surface 622 of the second metal structure 62 connects to the second contact 42 and has a third width W3. The third top surface 621 has a fourth width W4 larger than the third width W3. In the embodiment, since the third top surface 621 is lower than the fourth top surface 521, the second metal structure 62 is devoid of covering the fourth top surface 521 of the passivation structure 50. The second pad 72 is disposed on the second metal structure 62 and the passivation structure 50 and covers the third top surface 621 and the fourth top surface 521.

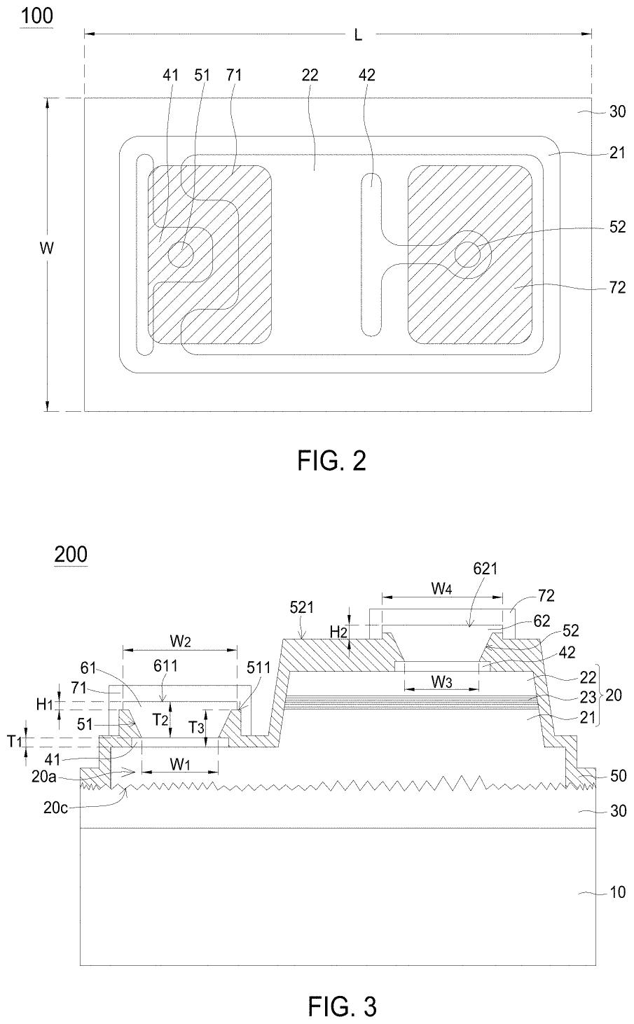

FIG. 2 is a schematic top view of a semiconductor device 100. In the embodiment, the semiconductor device 200 has a length L and a width W. The length L is not larger than 750 μm, such as 20 μm to 750 μm, or 300 μm to 600 μm, or 120 μm to 200 μm. The width W is not larger than 400 μm, such as 100 μm to 400 μm, or 150 μm to 300 μm, or 200 μm to 275 μm.

FIG. 3 is a schematic cross-sectional view of a semiconductor device 200 in accordance with an embodiment of the present application. The structure of the semiconductor device 200 is similar to that of the semiconductor device 100, except to the relation between the first top surface 611 and the second top surface 511, and the relation between the third top surface 621 and the fourth top surface 521. In the embodiment, the first top surface 611 is higher than the second top surface 511, and the third top surface 621 is higher than the fourth top surface 521. That is, the first top surface 611 is farer to the lower region 20a than the second top surface 511, and the third top surface 611 is farer to the lower region 20a than the fourth top surface 521. The first height difference H1 and the second height difference H2 are less than 3 μm and larger than zero in the embodiment. The third thickness T3 is smaller than the sum of the first thickness T1 and the second thickness T2.

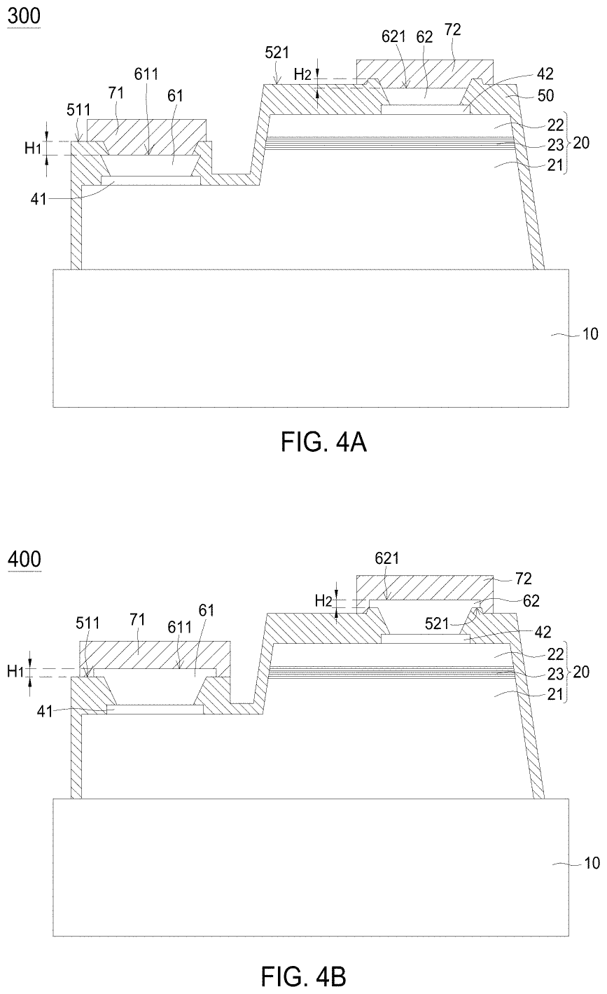

FIGS. 4A-4B are schematic cross-sectional view of embodiments of a semiconductor device 300, 400. The semiconductor devices 300, 400 have a structure similar to the semiconductor devices 100, 200. In the embodiments, the bonding layer 30 is omitted, and the epitaxial stack 20 physically connects the base 10. The epitaxial stack 20 can grow on the base 10 by epitaxial growth method. In other words, the base 10 can be a growth substrate of the epitaxial stack 20. The structure of the semiconductor device 300 is similar to that of the semiconductor device 100. That is, the first top surface 611 is lower than the second top surface 511, and the third top surface 621 is lower than the fourth top surface 521. The structure of the semiconductor device 400 is similar to that of the semiconductor device 200.

That is, the first top surface 611 is higher than the second top surface 511, and the third top surface 621 is higher than the fourth top surface 521. The first height difference H1 and the second height difference H2 are less than 3 μm and larger than zero in the embodiments.

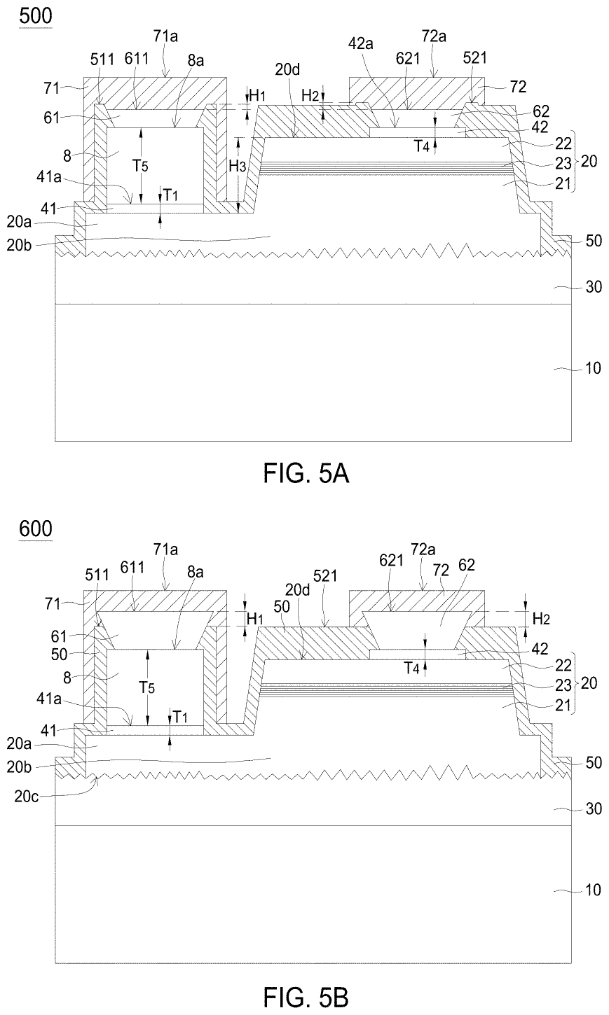

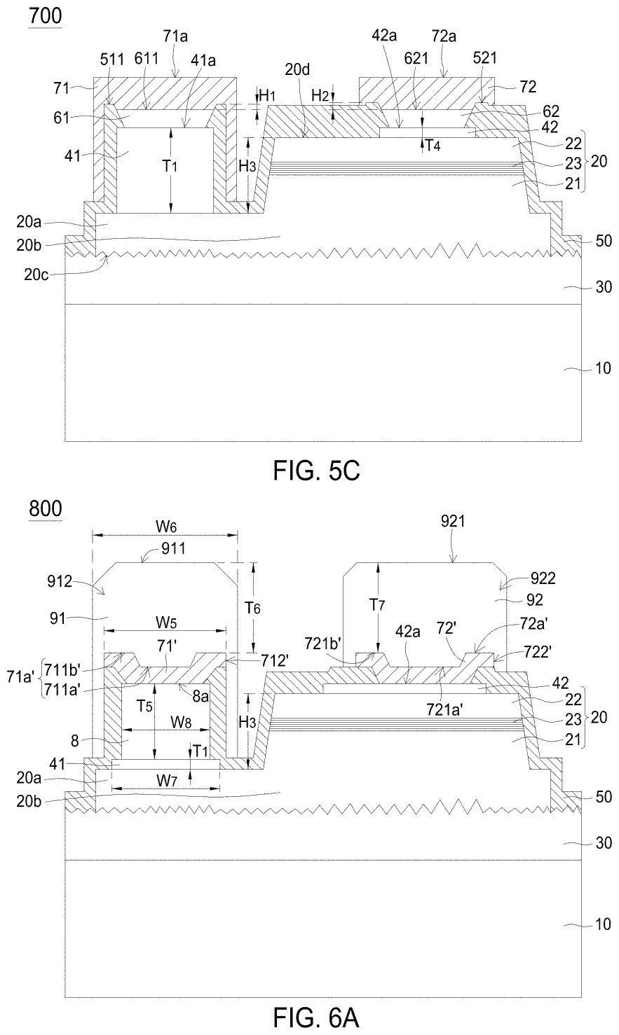

FIG. 5A is a schematic cross-sectional view of an embodiment of a semiconductor device 500. The semiconductor device 500 has a structure similar to the semiconductor devices 100. In this embodiment, the semiconductor device 500 includes a connector 8 between the first contact 41 and the first metal structure 61 for facilitating the bonding success rate when attaching the semiconductor device 500 to a circuit board. In the embodiment, the connector 8 locates between the first contact 41 and the first metal structure 61 and has a height enough to make the first top surface 611 of the first metal structure 61 and the third top surface 621 of the second metal structure 62 approximately coplanar. The first contact 41 includes a fifth top contact surface 41a away from the epitaxial stack 20 and the second contact 42 includes a sixth top contact surface 42a away from the epitaxial stack 20. The epitaxial stack 20 has a mesa surface 20d at the mesa region 20b. The connector 8 locates on the fifth top contact surface 41a and includes a connecting surface 8a away from the epitaxial stack 20, and the connecting surface 8a is higher than the mesa surface 20d and coplanar with the sixth top contact surface 42a. The connector 8 has a part covered by the passivation structure 50. The first pad 71 includes a first pad surface 71a away from the epitaxial stack 20 and the second pad 72 includes a second pad surface 72a away from the epitaxial stack 20. The second pad surface 72a is approximately coplanar with the first pad surface 71a.

In this embodiment, the first top surface 611 is lower than the second top surface 511, and the first height difference H1 between the first top surface 611 and the second top surface 511 is less than 3 μm and larger than zero. The third top surface 621 is lower than the forth top surface 521, and the second height difference H2 between the third top surface 621 and the fourth top surface 521 is less than 3 μm and larger than zero.

The embodiment of the semiconductor device 600 shown in FIG. 5B is similar to that shown in FIG. 5A. In the embodiment, the first top surface 611 is higher than the second top surface 511 and the third top surface 621 is higher than the fourth top surface 521. The first height difference H1 and the second height difference H2 are less than 3μm and larger than zero. In the embodiments shown in FIGS. 5A and 5B, the material of the connector 8 has high electrical conductivity and includes Au, Ni, Ti, Cu, Al, Pt, Pd, Ag, Ge, Be, Zn or the alloy thereof. In the embodiment, the third height difference H3 is between 2 μm and 6 μm. The connector 8 includes a fifth thickness T5, and the sum of the fifth thickness T5 and the first thickness T1 is approximately equal to the sum of the third height difference H3 and the fourth thickness T4. That is T5+T1=H3+T4. In the embodiment, the fifth thickness T5 is between 2 μm and 6 μm.

The embodiment of the semiconductor device 700 shown in FIG. 5C is similar to that shown in FIG. 5A. In the embodiment, the semiconductor device 700 is devoid of the connector 8. Instead, the first contact 41 has a thickness approximately the same as the sum of the third height difference H3 that exists between the mesa region 20b and the lower region 20a and the fourth thickness T4 of the second contact 42. The first contact 41 includes a fifth top contact surface 41a away from the epitaxial stack 20 and coplanar with a sixth top contact surface 42a of the second contact 42 away from the epitaxial stack 20. The epitaxial stack 20 has a mesa surface 20d at the mesa region 20b. The fifth top surface 41a is higher than the mesa surface 20d of the epitaxial stack 20. The fifth top contact surface 41a of the first contact 41 is higher than the active region 23. In an embodiment, a height difference between the fifth top surface 41a and the sixth top contact surface 42a is less than or equal to 10% of the height of the first contact 41. For example, the height difference is between 0% and 10% (both included) of the height of the first contact 41. In an embodiment, the first contact 41 physically contacts the first semiconductor structure 21, and the second contact 42 physically contacts the second semiconductor structure 22. In the embodiment, the first thickness T1 is approximately equal to the sum of the third height difference H3 and the fourth thickness T4. That is T1=H3+T4. In the embodiment, the first thickness T1 is between 3 μm and 6 μm.

The base 10 can be used to support the epitaxial stack 20 and the other element thereon. The base 10 can be conductive, semi-conductive or insulating. The base 10 also can be transparent, semi-transparent or non-transparent. The base 10 can be used as a growth substrate that the epitaxial stack 20 is directly grown on by MOCVD, MBE, HVPE or other epitaxial method. Alternatively, the epitaxial stack 20 can also be grown on a growth substrate (not shown) and then transfer to connect to the base 10 by substrate transferring technique, and the growth substrate can be removed. In one embodiment, the epitaxial stack 20 is transferred from a growth substrate, and connects to the base 10 by the bonding layer 30.

The material of the base 10 can include transparent insulating material, or transparent conductive oxide, semiconductor material or metal. The transparent insulating material can be diamond, glass, quartz, acryl, epoxy, aluminum nitride, or sapphire. The transparent conductive oxide can be zinc oxide (ZnO), indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), indium zinc oxide(IZO), tungsten doped indium oxide (IWO), gallium oxide (Ga₂O₃), lithium gallium oxide (LiGaO₂), lithium aluminum oxide (LiAlO₂) or aluminum magnesium oxide (MgAl₂O₄). The semiconductor material can be silicon carbide (SiC), gallium arsenide (GaAs), gallium phosphide (GaP), gallium arsenide phosphide (GaAsP), zinc selenide (ZnSe) or indium phosphide (InP). The metal can be aluminum (Al), copper(Cu), molybdenum (Mo), tungsten (W) or the combination of the above elements. In this embodiment, the base includes transparent insulating material, such as sapphire.

The active region 23 can produce light when the current flows into the epitaxial stack 20. The first semiconductor structure 21 and the second semiconductor structure 22, such as a cladding layer or a confinement layer, have different conductivity types, electrical properties, polarities, or doping elements for providing electrons or holes. For example, the first semiconductor structure 21 is a p-type semiconductor, and the second semiconductor structure 22 is an n-type semiconductor, or vice versa. The semiconductor device 100˜700 can be a single heterostructure (SH), a double heterostructure (DH), or a double-side double heterostructure (DDH). The active region 23 can be a multi-quantum well structure (MQW). The active region 23 can be i-type, p-type, or n-type semiconductor.

The materials of the first semiconductor structure 21, the second semiconductor structure 22 and the active region 23 include III-V group semiconductor compounds, such as GaAs, InGaAs, AlGaAs, AlInGaAs, GaP, InGaP, AlInP, AlGaInP, GaN, InGaN, AlGaN, AlInGaN, AlAsSb, InGaAsP, InGaAsN, or AlGaAsP. In the embodiments of the present disclosure, if not described otherwise, the above-mentioned chemical formulas include “stoichiometric compounds” and “non-stoichiometric compounds”. A “stoichiometric compound” is, for example, a compound in which the total number of atoms of III-group elements is the same as the total number of atoms of V-group elements. On the contrary, a “non-stoichiometric compound” is, for example, a compound in which the total number of atoms of III-group elements is different from the total number of atoms of V-group elements. For example, a compound has a chemical formula of AlGaAs represents that the compound includes Al and/or Ga as III-group elements, and As as V-group element, wherein the total number of atoms of the III-group elements (Al and/or Ga) and the total number of atoms of the V-group elements (As) are the same or different. In addition, if the above-mentioned compounds represented by the chemical formulas are stoichiometric compounds, then AlGaAs represents for Alₓ₁Ga₍₁₋ₓ₁₎As, wherein 0≤x1≤1; AlInP represents for Alₓ₂In₍₁₋ₓ₂₎P, wherein 0≤x2≤1; AlGaInP represents for (AlyGa_{(1-y1)}₁₋ₓ₃InxP, wherein 0≤x3≤1, and 0≤y1≤1; AlGaN represents for Alₓ₄Ga₍₁₋ₓ₄₎N, wherein 0≤x4≤1; AlAsSb represents for AlAsₓ5Sb₍₁₋ₓ₅₎, wherein 0≤x5≤1; InGaP represents for Inₓ₆Ga₁₋ₓ₆P, wherein 0≤x6≤1; InGaAsP represents for Inₓ₇Ga₁₋ₓ₇As-_{1-y2}P_{y2}, wherein 0≤x7≤1, and 0≤y2≤1; InGaAsN represents for InₓGa₁₋ₓAs_{1-y}N_{y}, wherein 0≤x8≤1, and 0≤y≤1; AlGaAsP represents for AlₓGa₁₋ₓAs_{1-y}P_{y}, wherein 0≤x9≤1, and 0≤y3≤1; InGaAs represents for Inxₓ₁₀Ga₁₋ₓ₁₀As, wherein 0≤x10≤1. When the semiconductor device 100˜700 in the disclosure is a light-emitting device, the epitaxial stack 20 can emit a light with a peak wavelength of about 200 nm˜1800 nm.

The bonding layer 30 includes an oxide material, such as zinc oxide (ZnO), indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), indium zinc oxide(IZO) , tungsten doped indium oxide (IWO), gallium oxide (Ga₂O₃), lithium gallium oxide (LiGaO2), lithium aluminum oxide (LiAlO₂), aluminum magnesium oxide (MgAl₂O₄). The bonding layer 30 is conductive or/and transparent to the light emitted from the active region 23.

The first contact 41 and the second contact 42 are able to form electrical contact with the first semiconductor structure 21 and the second semiconductor structure 22, respectively. The first contact 41 and the second contact 42 respectively include a conductive material, such as metal or alloy. The materials of the first contact 41 and the second contact 42 is respectively selected based on the materials of the first semiconductor structure 21 and second semiconductor structure 22, so that the first contact 41 and the second contact 42 form better electrical contacts (such as ohmic contacts) with the first semiconductor structure 21 and the second semiconductor structure 22, respectively. The metal includes Ge, Be, Zn, Au, Ni or Cu. The alloy includes two or more metals selected from the above-mentioned metals. The alloy includes GeAuNi, BeAu, GeAu, or ZnAu. For example, in an embodiment, the material of the first contact 41 is BeAu, and the material of the second contact 42 is GeAu. In the embodiment, the first contact 41 is single layer. For example, material compositions of the first contact 41 are uniformly distributed in the first contact 41. In another embodiment, the first contact 41 includes multiple layers, in which an apparent interface is present between any two layers or adjacent layers has different materials. When the first contact 41 includes multiple layers, the fifth top contact surface 41a of the first contact 41 is defined as an upper surface of an uppermost surface of the first contact 41. Similarly, the second contact 42 can be a single layer or includes multiple layers.

The passivation structure 50 can protect the sidewalls of the epitaxial stack 20, and can further selectively reflect light of a specific wavelength emitted from the active region 23 to outside of the semiconductor device 100 to enhance brightness. The passivation structure 50 includes one layer or multiple layers. When the passivation structure 50 includes multiple layers. Specifically, the passivation structure 50 can includes a plurality of pairs of layers to form a distributed Bragg reflector (DBR). A pair of layers includes a first layer and a second layer such as a SiOx layer and a TiOx layer. The first layer and the second layer have different refractive indices. The DBR provides a high reflectivity for particular wavelength or within a particular wavelength range by setting the refractive index difference between the first layer and the second layer. The thicknesses of the first layer and the second layer can be different or the same. The first layer in each pair can be the same or different, and the second layer in each pair can be the same or different.

The first metal structure 61 fills in the first opening 51 by deposition, electroplating or chemical plating. The first metal structure 61 is electrically conductive and has high thermal stability. The material of the first metal structure 61 includes Au, Ni, Ti, Cu, Al, Pt, Pd, Ag, Ge, Be, Zn or the alloy thereof. The production and the material of the second metal structure 62 can be referred to the first metal structure 61. In one embodiment, the first metal structure 61 or, the second metal structure 62 or both include a material having a standard reduction potential larger than 0.3 V.

The first pad 71 and the second pad 72 are locate on the same side of the epitaxial stack 20, and the semiconductor devices 100˜700 can form a horizontal type device. In one embodiment, the semiconductor device 100˜700 can be flip-bonded to a carrier, such as PCB, transparent board with TFT switcher or flexible board. The material of the first pad 71 and second pad 72 can be metal, metal alloy or transparent conductive material. The metal can be aluminum (Al), chromium (Cr), copper (Cu), tin (Sn), gold (Au), nickel (Ni), titanium (Ti), platinum (Pt), plumbum (Pb), zinc (Zn), cadmium (Cd), antimony (Sb), or cobalt (Co). The metal alloy includes the metal mentioned above. The transparent conductive material can be indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), zinc oxide (ZnO), aluminum gallium arsenide (AlGaAs), gallium nitride (GaN), gallium phosphide (GaP), gallium arsenide (GaAs), gallium arsenide phosphide (GaAsP), diamond-like carbon (DLC) or graphene. In the embodiments, the light emitted by the active region 23 can emit toward the base 10. Therefore, the first pad 71 and the second pad 72 can metal or metal alloy without considering whether the emitted light is blocked by the first pad 71 and the second pad 72.

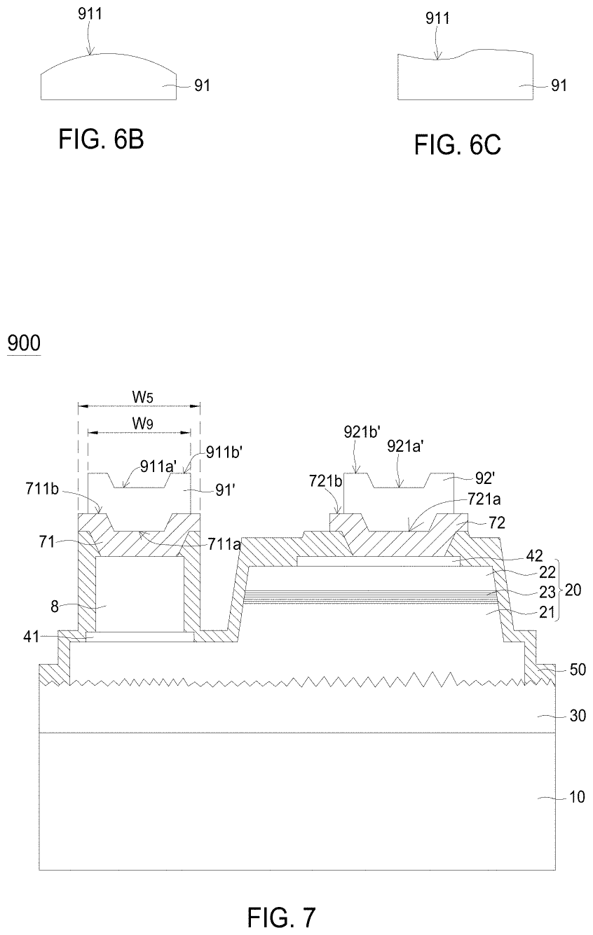

FIG. 6A is a schematic cross-sectional view of an embodiment of a semiconductor device 800. The semiconductor device 800 has a structure similar to the semiconductor device 600. The semiconductor device 800 does not include the first metal structure 61 and the second metal structure 62 and further includes a first metal bump 91 on the first pad 71′ and a second metal bump 92 on the second pad 72′. The first metal bump 91 includes a first upper surface 911 away from the epitaxial stack 20, and the second metal bump 92 includes a second upper surface 921 away from the epitaxial stack 20. The first pad 71′ includes a first pad surface 71a′ away from the epitaxial stack 20 and a first side surface 712′ connecting to the first pad surface 71a′, and the second pad 72′ includes a second pad surface 72a′ away from the epitaxial stack 20 and a second side surface 722′ connecting to the second pad surface 72a′. The first pad surface 71a′ includes a first concave portion 711a′ and a first convex portion 711b′, and the second pad surface 72a′ includes a second concave portion 721a′ and a second convex portion 721b′, while the first upper surface 911 and the second upper surface 921 are devoid of any concave portion and convex portion. In other words, the first metal bump 91 is not conformally formed on the first pad 71′ and the second metal bump 92 is not conformally formed on the second pad 72′. The first metal bump 91 and the first pad 71′ have different morphology, and the second metal bump 92 and the second pad 72′ have different morphology. The first metal bump 91 and the second metal bump 92 can fill in the first concave portion 711a′ of the first pad 71′ and the second concave portion 721a′ of the second pad 72′. In the embodiment, the first metal bump 91 and the second metal bump 92 respectively have cutting edges 912, 922 around the first upper surface 911 and second upper surface 921, and the first upper surface 911 is coplanar with the second upper surface 921. In the embodiment, the topmost point of the first upper surface 911 and the topmost point of the first upper surface 911 are approximately at the same height.

The first pad 71 includes a fifth width W5, and the first metal bump 91 includes a sixth width W6 larger than the fifth width W5. The first contact 41 includes a contact width W7, and the connector 8 includes a connector width W8 smaller than the contact width W7. The wider first contact 41 can reduce the contact resistance and avoid the heat gather at an interface between the first contact 41 and the first semiconductor structure 21. In the embodiment, the first metal bump 91 not only covers the first pad surface 71a of the first pad 71, but also covers the first side surface 712. The second metal bump 92 covers the second pad surface 72a and the second side surface 722 of the second pad 72. The first metal bumps 91 and the second metal bump 92 include tin or alloy of tin, such as SnAg or SnAgCu. The first metal bump 91 has a sixth thickness T6 and the second metal bump 92 has a seventh thickness T7, and the sixth thickness T6 and the seventh thickness T7 are at least 3 μm, and such as 4 μm to 20 μm. The sixth thickness T6 can be defined as the distance between the convex portion 711b and the first upper surface 911, and the seventh thickness T7 can be defined as the distance between the convex portion 721b and the second upper surface 921. In the embodiment, the sixth thickness T6 and the seventh thickness T7 are larger than the fifth thickness T5 of the connector 8. The first metal bump 91 locates only on the first region 20a and is devoid of covering the second region 20b for preventing the first metal bump 91 from damaged when depositing on the sidewall of the epitaxial stack 20 with the third height difference H3. The second metal bump 92 locates only on the second region 20b and is devoid of covering the first region 20a.

In other embodiments, the first upper surface 911 of the first metal bump 91 is arc-like shape as shown in FIG. 6B. More specifically, the first metal bump 91 includes a first bump convex portion at a position corresponding to the first concave portion 711a′. The second metal bump 92 includes a second bump convex portion at a position corresponding to the second concave portion 721a′. The first pad surface 71a includes a first morphology, and the first upper surface 911 includes a second morphology different from the first morphology. The different morphologies mean the specific surfaces have different roughness or concave-convex type. For example, the first pad surface 71a and the first upper surface 911 have different roughness, different numbers of convex and/ or concave from a cross section view of the semiconductor device. More specifically, the first upper surface 911 has one convex portion and no concave portion shown in FIG. 6B, and the first pad surface 71a has two convex portions and one concave portion shown in FIG. 6A.

As shown in FIG. 6C, the first upper surface 911 is an irregular shape. Specifically, the first upper surface 911 has one convex portion and one concave portion shown in FIG. 6C, and the first pad surface 71a has two convex and one concave shown in

FIG. 6A. In the embodiment.

FIG. 7 is a schematic cross-sectional view of an embodiment of a semiconductor device 900. The semiconductor device 900 has a structure similar to the semiconductor device 800. In this embodiment, the first metal layer 91′ includes a ninth width W9 smaller than the fifth width W5. The first metal layer 91′ and the second metal layer 92′ are respectively conformally formed on the first pad 71 and the second pad 72. More specifically, the first metal layer 91′ and the second metal layer 92′ include concave portion 911a′, 921a′ respectively align to the concave portion 711a of the first pad 71 and the concave portion 721a of the second pad 72. The first metal layer 91′ and the second metal layer 92′ include convex portions 911b′, 921b′ respectively align to the convex portion 711b of the first pad 71 and the convex portion 721b of the second pad 72.

In a process, when the semiconductor device 900 is subjected to a heat treatment at 200° C.-350° C. for a periods of time (20 minutes to 60 minutes), the first metal layer 91′ and the second metal layer 92′ changes their surface morphologies to form the first metal bump 91 and the second metal bump 92 as shown in FIGS. 6A-6C.

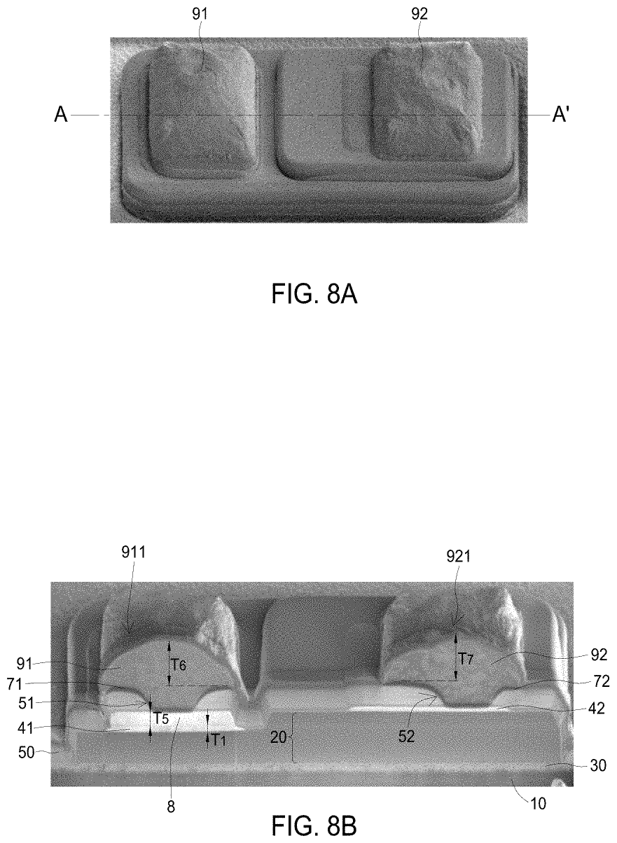

FIG. 8A is a SEM image of a semiconductor device in accordance with an embodiment of the present application. FIG. 8B is a SEM cross section view of semiconductor device along A-A′ line shown in FIG. 8A. The first upper surface 911 of the first metal bump 91 and the second upper surface 921 of the second metal bump 92 are arc-like shape.

In the present disclosure, the semiconductor device 100˜900 of the embodiments can be flip-chip mounted on another support member including circuits, and most of the radiation escapes to the outside of the semiconductor device 100˜900 from the base 10.

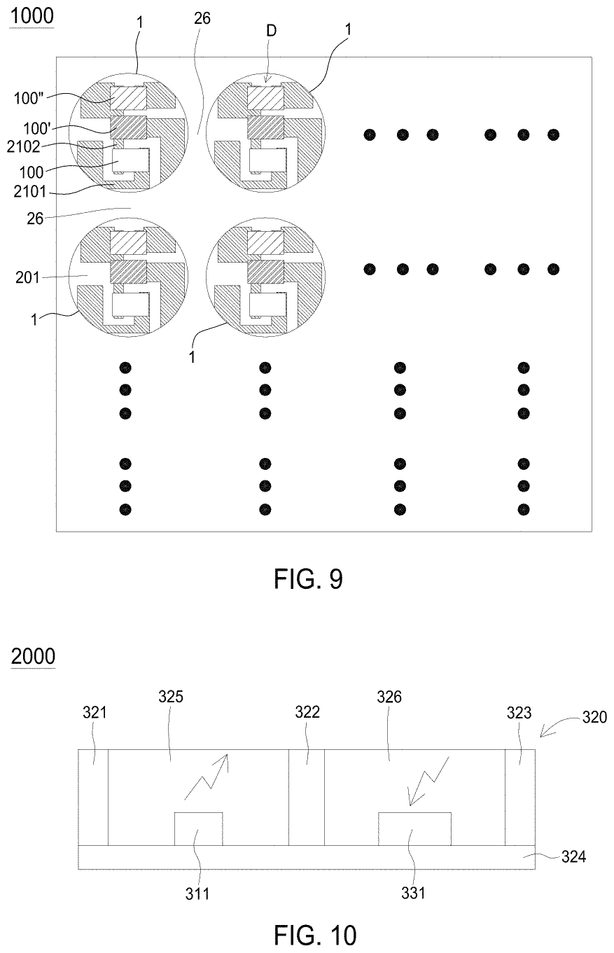

FIG. 9 shows a top view of a light-emitting module 1000 including the semiconductor device 100˜900 disclosed in the present disclosure. The light-emitting module 1000 includes a plurality of the semiconductor devices 100˜900. More specifically, the light-emitting module 1000 includes a plurality of semiconductor unit 1, and each of the semiconductor unit 1 includes three semiconductor elements 100, 100′, 100″ respectively emitting a first light, a second light and a third light. The structure of the semiconductor elements 100, 100′, 100″ can be the semiconductor devices 100˜900. The first light, the second light and the third light are mixed to form white light. For example, the first light is red light, the second light is green light, and the third light is blue light. In the embodiment, the plurality of the semiconductor elements includes a common carrier 201 and being arranged to form a two-dimensional array. Reflecting walls 26 locate between the adjacent semiconductor units 1. A concave part surrounded by reflecting wall 26 of the semiconductor units 1 could be circle as shown in the present embodiment, square, or slit depending on the application of the light-emitting module 1000. The concave part includes a concave area D, and the concave area D is preferably between 1 and 20 mm2. The light-emitting module 1000 can further be applied to a display device, such as television screen, cell phone screen, digital billboard, sporting digital signage. Each of the semiconductor units 1 is designated to be a pixel. The amount, color and arrangement of the semiconductor unit 1 and the distance between the neighboring semiconductor units 1 affect the visual property when the user watches the display device. For example, the display device has higher resolution by utilizing the semiconductor unit 1 with small size, since the display device accommodates much amount of the semiconductor unit 1 with small size than the semiconductor device 100 with large size.

FIG. 10 shows a cross sectional view of a part of a sensing module 2000. The sensing module includes a carrier 320, a first semiconductor element 311, and a second semiconductor element 331. The first semiconductor element 311 can be the semiconductor device 100˜900. The carrier 320 includes a first wall 321, a second wall 322, a third wall 323, a carrying board 324, a first space 325 and a second space 326. The first semiconductor element 311 locates in the first space 325 between the first wall 321 and the second wall 322. The second semiconductor element 331 locates in the second space 326 between the second wall 322 and the third wall 323. The first semiconductor element 311 can be horizontal chip as shown in FIGS. 1A, 3-6A. The first semiconductor element 311 and the second semiconductor element 331 dispose on the carrying board 324 and electrically connect to the circuit connecting structure (not shown) on the carrying board 324. In the embodiment, the first semiconductor element 311 can be a light-emitting device, and the second semiconductor element 331 can be a light-receiving device. In application, the sensing module 2000 can be placed in a wearable gadget (such as watch and earphone). The light emitted by the first semiconductor element 311 is absorbed by a target (such as cells or blood in the body) and the second semiconductor element 331 receives the light reflected/scattered by the target so that the physiological signal of the body, such as heart rate, blood sugar, blood pressure, blood oxygen saturation can be detected by the sensing module 2000

The semiconductor device, the light-emitting module and the sensing module can be applied in the products for lighting, medical care, display, sensing, electrical source system, such as lamp, surveillance, cell phone, tablet, mobile dashboard, television, computer, wearable gadget (ex: watch, earphone, bracelets, necklace and so on), traffic sign, outdoor signage, medical equipment.

The foregoing description of preferred and other embodiments in the present disclosure is not intended to limit or restrict the scope or applicability of the inventive concepts conceived by the Applicant. In exchange for disclosing the inventive concepts contained herein, the Applicant desires all patent rights afforded by the appended claims. Therefore, it is intended that the appended claims include all modifications and alterations to the full extent that they come within the scope of the following claims or the equivalents thereof.

What is claimed is:

1. A semiconductor device comprising:
an epitaxial stack comprising a mesa region and a lower region;
a first pad on the lower region and a second pad on the mesa region;
a first contact between the epitaxial stack and the first pad;
a passivation structure covering the epitaxial stack and comprising a first opening; and
a first metal structure in the first opening and disposed between the first contact and the first pad;
wherein the first metal structure comprises a first top surface away from the epitaxial stack, and the passivation structure comprising a second top surface at a position corresponding to the lower region and away from the epitaxial stack, and a first height difference between the first top surface and the second top surface is less than 3 um and larger than zero; and
wherein the first metal structure comprises a first width adjacent to the first contact and a second width adjacent to the first pad, and the second width is larger than the first width.

2. The semiconductor device according to claim 1, wherein the second top surface is closer to the lower region than the first top surface to the lower region.

3. The semiconductor device according to claim 1, wherein the first pad covers the second top surface of the passivation structure.

4. The semiconductor device according to claim 1, wherein the first top surface is closer to the lower region than the second top surface to the lower region.

5. The semiconductor device according to claim 1, further comprising a base and a bonding layer between the epitaxial stack and the base.

6. The semiconductor device according to claim 1, further comprising a base physically connects to the epitaxial stack.

7. The semiconductor device according to claim 1, wherein the passivation structure comprises a second opening, and the semiconductor device further comprises a second metal structure in the second opening; and wherein the second metal structure comprises a third top surface away from the epitaxial stack, and the passivation structure comprises a fourth top surface at a position corresponding to the mesa region and away from the epitaxial stack, and a second height difference between the third surface and the fourth top surface is less than 3 μm and larger than zero.

8. The semiconductor device according to claim 7, further comprising a second contact between the mesa region and the second metal structure, wherein the second metal structure comprises a third width adjacent to the second contact and a fourth width adjacent to the second pad, and the fourth width is larger than the third width.

9. The semiconductor device according to claim 1, wherein the first contact comprises a first thickness and the first metal structure comprises a second thickness larger than the first thickness.

10. The semiconductor device according to claim 8, wherein the passivation structure comprises a third thickness, and the second thickness is smaller than the third thickness.

11. The semiconductor device according to claim 8, further comprising a third height difference between the mesa region and the lower region, wherein the first contact comprises a first thickness and the second contact comprises a fourth thickness, and the first thickness is substantially equal to a sum of the third height difference and the fourth thickness.

12. The semiconductor device according to claim 1, wherein the epitaxial stack comprises a mesa surface at the mesa region and the first contact comprises a fifth top surface higher than the mesa surface.

13. The semiconductor device according to claim 1, further comprising a connector between the first contact and the first metal structure.

14. The semiconductor device according to claim 13, wherein the connector comprises a connecting surface away from the epitaxial stack and the epitaxial stack comprises a mesa surface at the mesa region and away from the epitaxial stack, and the connecting surface is higher than the mesa surface.

15. The semiconductor device according to claim 13, wherein the connector has a part covered by the passivation structure.

16. A semiconductor device comprising:
an epitaxial stack comprising a mesa region and a lower region;
a first contact on the lower region and a second contact on the mesa region;
a first pad on the first contact and comprising a first concave portion;
a second pad on the second contact; and
a first metal bump on the first pad and comprising a first bump convex portion.

17. The semiconductor device according to claim 16, further comprising a second pad on the second contact and a second metal bump on the second pad, wherein the second pad comprises a second concave portion and the second metal bump comprises a second bump convex portion.

18. The semiconductor device according to claim 16, further comprising a connector between the first contact and the first pad, wherein the first contact comprises a first contact width and the connector comprises a connector width, and the connector width is small than the first contact width.

19. The semiconductor device according to claim 18, wherein the connector comprises a thickness and the first metal bump comprises a thickness larger than that of the connector.

20. The semiconductor device according to claim 16, wherein the first pad comprises a first side surface connecting to the first top surface, and the first metal bump covers the first top surface and the first side surface.
